(19) United States
(12) Patent Application Publication
(10) Pub. No.: US 2021/0091642 A1
(43) Pub. Date: Mar. 25, 2021

(54) CIRCUIT SUBSTRATE AND ELECTRIC OIL PUMP

(71) Applicant: NIDEC TOSOK CORPORATION, Kanagawa (JP)

(72) Inventor: Yusaku SEKI, Kanagawa (JP)

(73) Assignee: NIDEC TOSOK CORPORATION, Kanagawa (JP)

(21) Appl. No.: 17/017,705

(22) Filed: Sep. 11, 2020

(30) Foreign Application Priority Data
Sep. 20, 2019 (JP) 2019-171230

(51) Int. Cl. H02K 11/33; H05K 1/02; H02H 11/00; H02H 7/08; F04C 11/00

(52) U.S. Cl. CPC H02K 11/33; H05K 1/0213; H02H 11/003; H02H 7/08; H05K 2201/1009; H02K 2211/03; H05K 2201/10166; H05K 2201/10174; H05K 2201/10015; F04C 11/00

(57) ABSTRACT

A control substrate includes: a reverse connection protection circuit; a first substrate wiring connected with a source terminal of a MOSFET of the reverse connection protection circuit; a second substrate wiring connected with a GND terminal; a bypass circuit, allowing, in a case where an output voltage of a vehicle-mounted battery is equal to or greater than a predetermined value, a current to flow from the first substrate wiring to the second substrate wiring; and a clamp circuit, connected with a positive electrode terminal and a GND terminal on an upstream side with respect to the MOSFET and clamps a positive voltage to a second predetermined value. The first predetermined value is a value smaller than a withstand voltage between a gate and a source of the MOSFET.

### CROSS-REFERENCE TO RELATED APPLICATIONS

The present invention claims priority under 35 U.S.C. § 119 to Japanese Application No. 2019-171230, filed on Sep. 20, 2019, the entire content of which is incorporated herein by reference.

### FIELD OF INVENTION

The disclosure relates to a circuit substrate and an electric oil pump.

### BACKGROUND

Conventionally, a circuit substrate including a substrate, a positive electrode terminal and a GND terminal for inputting a direct current (DC) external power supply, and a reverse connection protection circuit which protects circuits in a substrate in the case where the positive/negative of the external power supply are connected with the positive electrode terminal and the GND terminal in reverse is known.

For example, a conventional circuit substrate includes a positive power supply terminal, which is the positive electrode terminal, a negative power supply terminal, which is the GND terminal, and a reverse connection protection circuit. The reverse connection protection circuit includes a metal oxide semiconductor FET (MOSFET).

In the conventional circuit substrate, in the case of being connected with an external power supply with the possibility of generating a transient overvoltage (transient surge), such as a sudden pulse that is twice or more of the rated voltage, the use of a high withstand voltage MOSFET as a countermeasure is considered. However, when the high withstand voltage MOSFET is used, the cost is increased.

### SUMMARY

According to an exemplary embodiment of the disclosure, a circuit substrate includes: a substrate; a positive electrode terminal and a GND terminal for inputting a direct current (DC) external power supply; and a reverse connection protection circuit, protecting a circuit in the substrate in a case in which positive/negative of the external power supply are connected with the positive electrode terminal and the GND terminal in reverse. The reverse connection protection circuit comprises a MOSFET, and the circuit substrate includes: a first substrate wiring, connected with a source terminal of the MOSFET; a second substrate wiring, connected with the GND terminal; a bypass circuit, allowing, in a case where an output voltage of the external power supply is equal to or greater than a first predetermined value, a current to flow from the first substrate wiring to the second substrate wiring; and a clamp circuit, connected with the positive electrode terminal and the GND terminal at an upstream side with respect to the MOSFET and clamping a positive voltage to a second predetermined value. The first predetermined value is a value smaller than a withstand voltage between a gate and a source of the MOSFET.

According to an exemplary embodiment of the disclosure, an electric oil pump includes: a pump part; a motor part driving the pump part; and a circuit substrate. The circuit substrate is the circuit substrate of the above exemplary embodiment of the disclosure.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is an exploded perspective view illustrating an electric oil pump according to an embodiment of the disclosure from the +X side.

FIG. 2 is an exploded perspective view illustrating the electric oil pump from the −X side.

FIG. 3 is a block diagram illustrating circuits of a control substrate in an inverter of the electric oil pump.

FIG. 4 is a circuit diagram illustrating part of the circuits in the control substrate.

FIG. 5 is a circuit diagram illustrating part of the circuits in a control substrate of an electric oil pump according to a modified example.

### DETAILED DESCRIPTION

Hereinafter, an electrical oil pump according to an embodiment of the disclosure will be described with reference to the drawings. In the embodiment, an electric oil pump mounted on a vehicle such as an automobile will be described. In addition, in the following drawings, the scale and number of each structure may be different from the actual structure in order to make the structure easy to understand.

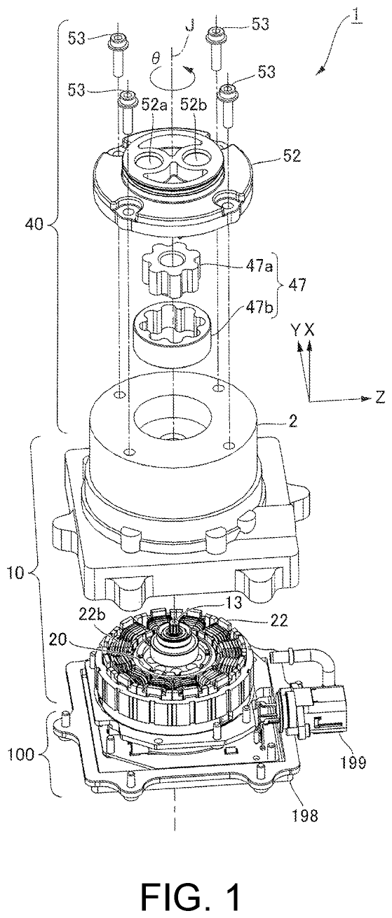

Further, in the drawings, an XYZ coordinate system is appropriately shown as a three-dimensional orthogonal coordinate system. In the XYZ coordinate system, the X-axis direction is parallel to the axial direction of the center axis J shown in FIG. 1. The center axis J is a center axis of a shaft (motor shaft) 13 of a motor part 10 described later. The Y-axis direction is parallel to the lateral direction of the electric oil pump shown in FIG. 1. The Z-axis direction is a direction orthogonal to both the X-axis direction and the Y-axis direction. In any of the X-axis direction, the Y-axis direction, and the Z-axis direction, the side indicated with the arrow shown in the drawings is the “+” side, and the opposite side is the “−” side.

In addition, in the following descriptions, the positive side of the X-axis direction (+X side) is referred to as “front side”, and the negative side of the X-axis direction (−X side) is referred to as “rear side”. Nevertheless, the rear side and the front side are merely terms used for descriptions and shall not serve to limit the actual position relationship and direction. The front side (+X side) is equivalent to “one side” in the disclosure, and the rear side (−X side) is equivalent to “the other side” in the disclosure. Unless otherwise specified, the direction parallel to the center axis J (X-axis direction) is simply referred to as “axial direction”, the radial direction with the center axis J as the center is simply referred to as “radial direction”, and the circumferential direction around the center axis J, that is, the circumference of the center axis J (θ direction) is simply referred to as “circumferential direction”.

In this specification, the phrase “extending in the axial direction” includes not only a case of extending strictly in the axial direction (X-axis direction), but also a case of extending in a direction inclined by less than 45° with respect to the axial direction. Further, in this specification, the phrase “extending in the radial direction” includes not only a case of extending strictly in the radial direction, that is, a direction perpendicular to the axial direction (X-axis direction), but also a case of extending in a direction inclined by less than 45° with respect to the radial direction.

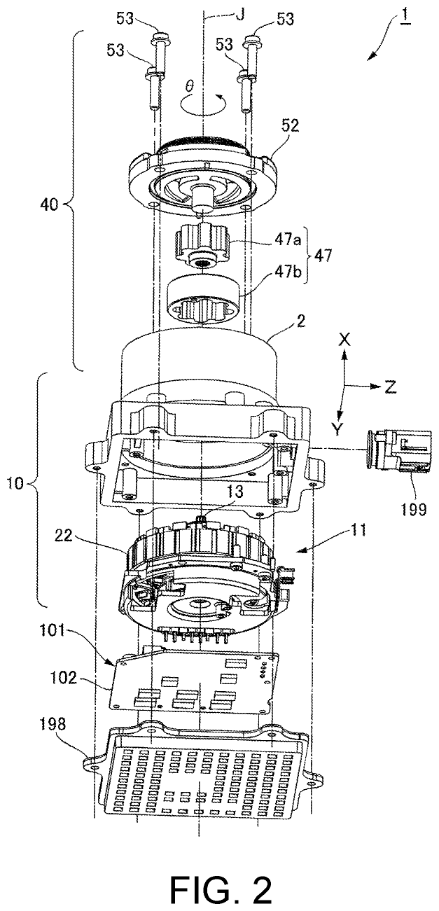

FIG. 1 is an exploded perspective view illustrating an electric oil pump 1 according to an embodiment of the disclosure from the +X side. FIG. 2 is an exploded perspective view illustrating the electric oil pump 1 from the −X side. The electric oil pump 1, as shown in FIGS. 1 and 2, includes a housing 2, a motor part 10, a pump 40, and an inverter 100.

The housing 2 is a casting made of metal (e.g., aluminum). The housing 2 also serves as a motor housing for the motor part 10, a pump housing for the pump part 40, and an inverter housing for the inverter 100. The motor housing for the motor part 10, the pump housing for the pump part 40, and the inverter housing for the inverter 100 are portions of a single member.

A rotor accommodating part of the pump part 40 that accommodates a pump rotor and the motor housing for the motor part 10 may be portions of a single member and may also be separate bodies. In addition, the motor housing for the motor part 10 and the pump housing for the pump part 40 may also be separate bodies.

When the motor housing and the pump housing are portions of a single member as in the electric oil pump 1 according to the embodiment, the axial boundary between the motor housing and the pump housing is defined in the following. That is, the axial center of a wall provided with a through hole that the shaft penetrates through from inside the motor housing toward the rotor accommodating part of the pump housing is the axial boundary of the two housings.

The motor part 10 includes a motor 11 in the motor housing.

The motor 11 includes a shaft 13 disposed along the center axis J extending along the axial direction, a rotor 20, and a stator 22.

The motor 11, for example, is an inner rotor type motor, and the rotor 20 is fixed to an outer peripheral surface of the shaft 13, and the stator 22 is disposed on a radially outer side of the rotor 20. A portion of the motor 11, excluding the shaft 13, is the main body of the motor 11. That is, the main body of the motor 11 includes the rotor 20, the stator 22, etc.

The rotor 20 is fixed to a region on the rear side (the other side) of the shaft 13 and on the front side (the one side) with respect to the end of the rear side. The stator 22 is disposed so that the inner peripheral surface faces the outer peripheral surface of the rotor 20.

The axially front side of the shaft 13 as the motor shaft protrudes from the end of the front side of the stator 22 to be connected with the pump part 40 (more specifically, a pump rotor 47 to be described afterwards).

The stator 22 includes a coil 22b. When power is supplied to the coil 22b, the rotor 20 rotates together with the shaft 13.

The housing 2 includes an opening facing the axially rear side at the end of the axially rear side. The opening is blocked by an inverter cover 198. By removing the inverter cover 198 from the housing 2, an operator can access a control substrate 101 of the inverter 100.

The pump part 40 is located on the axially front side of the motor part 10, and is driven by the motor part 10 via the shaft 13 to discharge oil. The pump part 40 includes the pump rotor 47 and a pump cover 52.

The pump rotor 47 is attached to the front side of the shaft 13. The pump rotor 47 includes an inner rotor 47a and an outer rotor 47b. The inner rotor 47a is fixed to the shaft 13. The outer rotor 47b surrounds the radially outer side of the inner rotor 47a.

The inner rotor 47a is in an annular shape or a substantially annular shape. The inner rotor 47a is a gear having teeth on the radially outer surface. The inner rotor 47a rotates along the circumference (θ direction) together with the shaft 13. The outer rotor 47b is in an annular shape or a substantially annular shape that surrounds the radially outer side of the inner rotor 47a. The outer rotor 47b is a gear having teeth on the radially inner surface. The radially outer surface of the outer rotor 47b is in a circular shape or a substantially circular shape.

The gear on the radially outer surface of the inner rotor 47a and the gear on the radially inner surface of the outer rotor 47b are meshed with each other, and the outer rotor 47b rotates as the inner rotor 47a rotates with the rotation of the shaft 13. That is, the pump rotor 47 rotates through rotation of the shaft 13. The motor part 10 and the pump part 40 include the shaft 13 that serves as the rotational shaft consisting of the same member. Accordingly, the electric oil pump 1 can be prevented from being increased in size in the axial direction.

In addition, through the rotation of the inner rotor 47a and the outer rotor 47b, the volume between the meshing portions of the inner rotor 47a and the outer rotor 47b changes. The region where the volume decreases is a pressurization region, and the region where the volume increases is a negative pressure region.

The housing 2 includes an opening facing the axially front side at the end of the axially front side. The opening is closed by the pump cover 52. The pump cover 52 is fixed to the housing 2 by a bolt 53. In addition, the pump cover 52 includes a discharging port 52a facing the pressurization region in the oil rotor 47 and a suction port 52b facing the negative pressure region in the pump rotor 47. When the pump rotor 47 rotates, the oil inside the pump part 40 is discharged to the outside via the discharging port 52a, and the oil outside is sucked into the pump part 40 via the suction port 52b.

The inverter 100 is disposed on the axial −X side with respect to the motor part 10 and the pump part 40. The inverter 100 that controls driving of the motor 11 includes the control substrate 101 as a circuit substrate, the inverter cover 198, and a connector 199.

The control substrate 101 includes a substrate 102 and a plurality of electronic component mounted on the substrate 102. The substrate 102 includes a plurality of substrate wirings, terminals, lands, through holes, test points, etc. The substrate 102 with such configuration on which a plurality of electronic component are mounted is the control substrate 101. That is, the portion of the control substrate 101 excluding the electronic component mounted thereon is the substrate 102. Part of the electronic component define a motor driving circuit including an inverter function.

The control substrate 101 is fixed inside the inverter housing in a posture at which a substrate surface are along the Y-axis direction and the Z-axis direction.

The connector 199 is connected with a power connector on the vehicle side. The power connector on the vehicle side includes four ports for constant power supply, for GND, for signal input, and signal output, and is attached to the connector 199 through moving, by the operator, from the +Z side toward the −Z side in the Z-axis direction. The connector 199 includes four connector terminals individually electrically connected with the four ports.

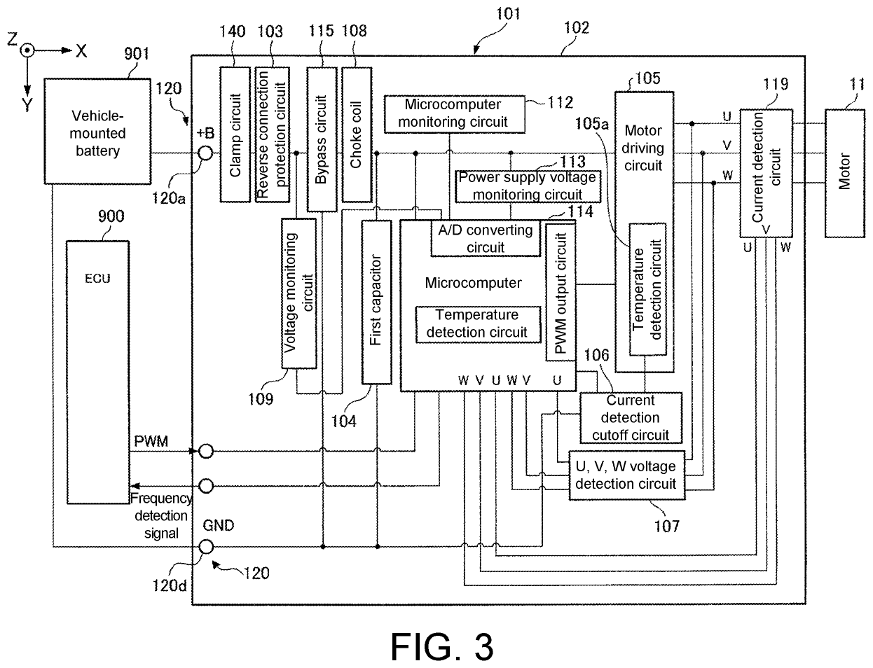

FIG. 3 is a block diagram illustrating circuits of the control substrate 101 of the inverter 100. The control substrate 101 includes a reverse connection protection circuit 103, a first capacitor 104, a motor driving circuit 105, a current detection cutoff circuit 106, a U, V, W voltage detection circuit 107, a choke coil 108, and a voltage monitoring circuit 109. In addition, the control substrate 101 includes a 5V power circuit 110, a microcomputer monitoring circuit 112, a power supply voltage monitoring circuit 113, a microcomputer 114, a bypass circuit 115, a current detection circuit 119, and a clamp circuit 140.

The power input part of the substrate 102 of the control substrate 101 is connected with a vehicle-mounted battery 901. The constant power supply of the vehicle-mounted battery 901 and GND are connected with the motor driving circuit 105 via the reverse connection protection circuit 103 and the first capacitor 104.

The reverse connection protection circuit 103 is a circuit that cuts off a negative voltage output toward the downstream side with respect to the reverse connection protection circuit 103 in the case where the constant power supply of the vehicle battery 910 is reversely connected with the GND.

The capacitor 104 is an electrolytic capacitor that absorbs the ripple current of the input power to stabilize voltage.

The power supply voltage monitoring circuit 113 is connected with substrate wirings which electrically connect the first capacitor 104 and the motor driving circuit 105. The power supply voltage monitoring circuit 113 detects the DC voltage output to the motor driving circuit 105, and outputs the detected value to an A/D converting circuit of the microcomputer 114.

The microcomputer 114 includes the A/D converting circuit, a PWM output circuit, and a temperature detection circuit. The microcomputer 114 receives a driving command signal consisting of PWM transmitted from an ECU 900 of the vehicle, and generates a PWM signal that drives the motor 11 to rotate at a frequency based on the driving command signal. The generated PWM signal is output from the PWM output circuit of the microcomputer 114 and input to the motor driving circuit 105.

The motor driving circuit 105 converts the DC power transmitted from the first capacitor into three-phase AC power whose frequency follows the PWM signal transmitted from the PWM output circuit 114a of the microcomputer 114 and outputs the three-phase alternating current (AC) power to the motor 11. The motor driving circuit 105 includes a plurality of bipolar transistors (MOSFETs) for switching and a temperature detection circuit 105a. The temperature detection circuit 105a of the motor driving circuit 105 outputs the detected temperature value to the current detection cutoff circuit 106.

The current detection cutoff circuit 106 detects the current flowing from the motor driving circuit 105 to the motor 11. When the detected current value exceeds a predetermined upper limit or the detected temperature value transmitted from the temperature detection circuit 105a of the motor driving circuit 105 exceeds a predetermined upper limit, the current detection cutoff circuit 106 outputs a cutoff signal to the microcomputer 114.

When the cutoff signal is transmitted from the current detection cutoff circuit 106 or the detected temperature value detected by the temperature detection circuit 114c of the microcomputer 114 exceeds the predetermined upper limit, the microcomputer 114 stops generating the PWM signal to stop driving of the motor 11.

The U, V, W voltage detection circuit 107 detects the voltage of the three-phase AC power output from the motor driving circuit 105 to the motor 11, and outputs the detected value to the A/D converting circuit of the microcomputer 114.

The 5V power circuit 110 is connected with the substrate wirings electrically connecting the reverse connection protection circuit 103 and the first capacitor 104 via the choke coil 108. The choke coil 108 is configured as a circuit that prevents the current flowing through the 5V power circuit 110 from becoming an overcurrent.

The microcomputer monitoring circuit 112 is connected with the microcomputer 114 and monitors whether there is any abnormality in the microcomputer 114 through communication with the microcomputer 114.

The voltage monitoring circuit 109 detects the voltage of the DC power transmitted from the choke coil 108 to the 5V power circuit 110, and outputs the detected value to the A/D converting circuit of the microcomputer 114.

The current detection circuit 119 detects a U-phase current, a V-phase current, and a W-phase current respectively output from the motor driving circuit 105, and output the detection result to the microcomputer 114. The microcomputer 114 analyzes the current waveform based on the current value transmitted from the current detection circuit 119 for each of the U-phase, the V-phase, and the W-phase. Then, the microcomputer 114 calculates the slip frequency based on the distortion of the current waveform, calculates the rotation frequency of the motor 11 based on the calculation result, the power frequency and the polar pairs, and outputs the calculation result as a frequency detection signal to an ECU 900 of the vehicle.

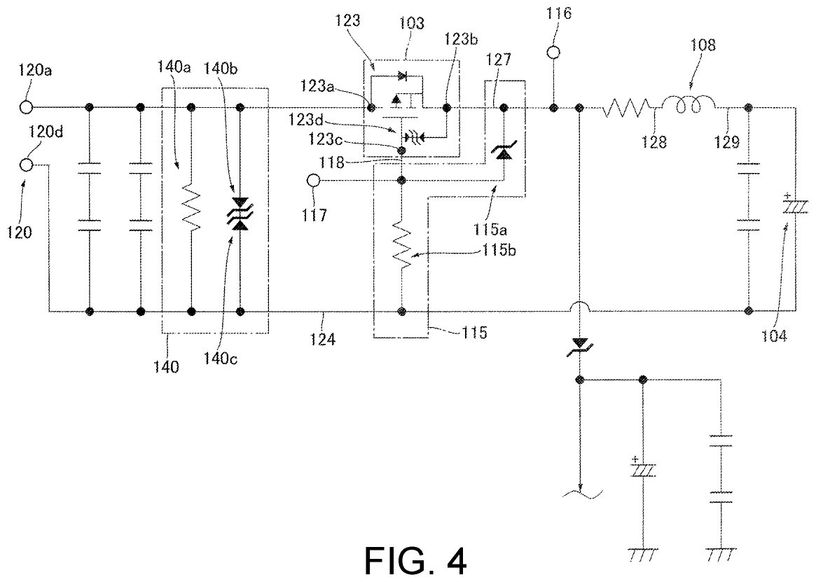

FIG. 4 is a circuit diagram illustrating part of circuits in the control substrate 101, which is a circuit substrate. As shown in the same figure, the reverse connection protection circuit 103 includes a MOSFET 123. When a voltage is applied between a positive electrode terminal 120a and a GND terminal 120d in a power input part 120 of the control substrate 101, a voltage is applied between a source terminal 123b and a gate terminal 123c of the MOSFET 123. As shown in the figure, in the MOSFET 123, there is a parasitic diode that allows a current to flow from the left side toward the right side of the figure. When the positive/negative of the vehicle-mounted battery 901 are connected with the power input part 120 of the control substrate 101 in reverse, the MOSFET 123 is not turned on, but cuts off the output of the negative voltage toward the downstream side with respect to the reverse connection protection circuit 103. Accordingly, the respective circuits in the control substrate 101 are protected.

The control substrate 101 includes a first substrate wiring 127 connected with the source terminal 123b of the MOSFET 123, a second substrate wiring 124 connected with the GND terminal 120d, the bypass circuit 115, and the clamp circuit 140.

The bypass circuit 115 is a circuit which, in the case where the output voltage of the vehicle-mounted battery 901 as the external power supply is equal to or greater than a first predetermined value greater than the rating (e.g., 12 V), allows a current to flow from the first substrate wiring 127 toward the second substrate wiring 124. The first predetermined value (referred to as “bypass opening value” in the following) is a value smaller than a withstand voltage between the gate and the source of the MOSFET 123. As an example, the rating voltage of the vehicle-mounted battery 901 is 12[V], and the withstand voltage between the gate and the source of the MOSFET 123 is 20[V]. Between the drain and the source of the MOSFET 123, the positive withstand voltage is from 57[V] (room temperature) to 60[V] (−40° C.), and the negative withstand voltage is from −57[V] (room temperature) to −60[V] (−40° C.), for example. The bypass opening value of the bypass circuit 115 is 16[V], for example. In the following, while the configuration of the control substrate 101 is described by using the above example, the combination of the rating voltage of the vehicle-mounted battery 901, the withstand voltage between the gate and the source of the MOSFET 123, the withstand voltage between the drain and the source of the MOSFET 123, and the bypass opening value is not limited to the above example. However, the withstand voltage between the drain and the source is generally higher than the withstand voltage between the gate and the source.

(1) The control substrate 101 of the electric oil pump 1 includes the substrate 102, the positive electrode terminal 120a and the GND terminal 120d for inputting the DC ignition power supply, and the reverse connection protection circuit 103. The reverse connection protection circuit 103 includes the MOSFET 123, and protects the circuits in the substrate 102 in the case where the positive/negative of the ignition power supply are connected in reverse. The control substrate 101 includes the first substrate wiring 127 connected with the source terminal 123b of the MOSFET 123, the second substrate wiring 124 connected with the GND terminal 120d, and the bypass circuit 115. In addition, the control substrate 101 includes the clamp circuit 140 which is connected with the positive electrode terminal 120a and the GND terminal 120d on the upstream side with respect to the MOSFET and clamps a positive voltage to a second predetermined value. The bypass circuit 115 allows, in the case where the output voltage of the external power supply is equal to or greater than the bypass opening value (the first predetermined value), a current to flow from the first substrate wiring 127 toward the substrate wiring 124. The bypass opening value (which is equal to 16[V], for example) is a value smaller than the withstand voltage (which is equal to 20[V], for example) between the gate and the source of the MOSFET 123.

In the control substrate 101, in the state in which the positive/negative of the vehicle-mounted battery 910 are properly connected, the voltage input to the power input part 120 starts to become higher than the rating of 12[V], for example. Then, the voltage input to the power input part 120 reaches 16[V], for example, which is the bypass opening value, before reaching 20[V], for example, which is the withstand voltage between the gate and the source of the MOSFET 123. Then, with the current flowing from the side of the source terminal 123b of the MOSFET 123 toward the side of the GND terminal 120d, the bypass circuit 115 maintains the voltage between the gate and the source of the MOSFET 123 to be lower than 20[V] (lower than the withstand voltage), for example. Therefore, in the control substrate 101, a voltage equal to or greater than the withstand voltage between the gate and the source can be prevent from being applied between the gate and the source of the MOSFET 123 by the bypass circuit 115.

In the MOSFET 123, while the voltage between the gate and the source is maintained to be lower than the withstand voltage between the gate and the source by the bypass circuit 115, there is still concern that an overvoltage may be applied between the drain and the source when a transient surge occurs due to electrostatic discharge, etc. Therefore, the control substrate 101 includes the clamp circuit 140 on the upstream side with respect to the MOSFET 123. The clamp circuit 140 prevents an overvoltage from being applied between the drain and the source of the MOSFET 123 by clamping the positive voltage input to the power input part 120 to the second predetermined value.

Each of the bypass circuit 115 and the clamp circuit 140 can be configured with a cost-effective electronic component such as a varistor or a Zener diode, etc.

Therefore, with the control substrate 101, the damage to the gate of the MOSFET 123 due to the overvoltage between the gate and the source can be prevented at a cost lower than the case of using a high withstand voltage (e.g., twice or more of the rating voltage of the external power supply) MOSFET. In addition, with the control substrate 101, the damage to the parasitic diode of the MOSFET 123 due to the overvoltage between the drain and the source can be prevented at a cost lower than the case of using a high withstand voltage MOSFET.

(2) In the control substrate 101, the clamp circuit includes a diode pair (140b and 140c), which is a pair of Zener diodes which are serially connected with each other to allow a current flowing in an opposite direction. Then, the clamp circuit 140 clamps the positive voltage to the second predetermined value, and clamps a negative voltage to a third predetermined value.

In the control substrate 101 with such configuration, by using the simple configuration like the diode pair, regardless of the positive or negative polarity, the damage of the overvoltage between the drain and the source made to the parasitic diode of the MOSFET 123 is prevented. Therefore, according to the control substrate 101, the damage to the parasitic diode resulting from a transient surge due to electrostatic discharge can be prevented.

(3) In the control substrate 101, the second predetermined value is a value smaller than the withstand voltage on the positive polarity side between the drain and the source of the MOSFET 123.

In the control substrate 101 with such configuration, in the case where a positive overvoltage is input, with the clamp circuit 140 clamping the voltage to the second predetermined value, the voltage between the drain and the source of the MOSFET 123 is maintained at a value lower than the withstand voltage on the positive polarity side between the drain and the source. Therefore, according to the control substrate 101, the damage to the parasitic diode of the MOSFET 123 due to input of a positive overvoltage to the control substrate 101 can be reliably prevented.

(4) In the control substrate 101, the absolute value of the third predetermined value is a value smaller than the absolute value of the withstand voltage on the negative polarity side between the drain and the source of the MOSFET 123.

In the control substrate 101 with such configuration, in the case where a negative overvoltage is input, the clamp circuit 140 clamps the absolute value of the negative voltage to the third predetermined value. With such clamping, the clamp circuit 140 maintains the negative voltage between the drain and the source of the MOSFET 123 at a value lower than the negative withstand voltage between the drain and the source. Therefore, according to the control substrate 101, the damage to the parasitic diode of the MOSFET 123 due to input of a negative overvoltage to the control substrate 101 can be reliably prevented.

(5) In the control substrate 101, each of the second predetermined value and the absolute value of the third predetermined value is a value greater than the bypass opening value (the first predetermined value).

In a conventional MOSFET, the withstand voltage between the drain and the source is greater than the withstand voltage between the gate and the source. Therefore, the clamp circuit 140 of the control substrate 101 clamps the voltage between the drain and the source to a value (the second predetermined value, the absolute value of the third predetermined value) greater than the bypass opening value (the first predetermined value). According to the control substrate 101 with such configuration, the damage to the parasitic diode of the MOSFET 123 due to an overvoltage input to the control substrate 101 can be prevented without an expensive and large power clamper.

In the case where a transient surge test for a vehicle-mounted device (e.g., ISO7637-2) is carried out for the control substrate 101, each of the second predetermined value and the absolute value of the third predetermined value may be set to be greater than the peak voltage of the surge waveform used in the test. For example, through the delivery destination of the control substrate 101, 35[V] is designated as the peak voltage. In this case, for example, if the withstand voltage between the drain and the source is +57[V] (room temperature) and −57[V] (room temperature), for example, a diode pair (140b and 140c) with a Zener voltage that sets each of the second predetermined value and the absolute value of the third predetermined value at the level of 37[V], for example, are used. Accordingly, the damage to the parasitic diode of the MOSFET 123 can be prevented without a large power clamper. However, regarding the individual electronic components disposed on the downstream side with respect to the MOSFET 123, those with a withstand voltage greater than 37[V], for example, are mounted so as not to be destructed in the transient surge test.

(6) The control substrate 101 includes a third substrate wiring 118 connected with the gate terminal 123c. The bypass circuit 115 includes a Zener diode 115a and a resistor 115b electrically interposed between the first substrate wiring 127 and the second substrate wiring 124 and serially connected with each other. The Zener diode 115a is electrically interposed between the first substrate wiring 127 and the third substrate wiring 118. The resistor 115b is electrically interposed between the third substrate wiring 118 and the second substrate wiring 124. The Zener voltage of the Zener diode 115a is lower than the withstand voltage between the gate and the source of the MOSFET 123.

In the control substrate 101 with such configuration, the output voltage from the vehicle-mounted battery 901, after starting to become higher than the rating, does not reach the withstand voltage between the gate and the source, but reaches the Zener voltage of the Zener diode 115a of the bypass circuit 115. Then, an Avalanche surrender phenomenon occurs in the Zener diode 115a, and a current flowing from the first substrate wiring 127 to the GND via the bypass circuit 115 is generated. Then, by generating the current, the voltage between the gate and the source in the MOSFET 123 is maintained to be lower than the withstand voltage between the gate and the source. Thus, according to the control substrate 101, by using the bypass circuit 115 including the Zener diode 115a and the resistor 115b, the damage to the gate of the MOSFET 123 can be prevented at a cost lower than the case of using a high withstand voltage MOSFET.

(7) The first predetermined value is the Zener voltage.

According to such configuration, the damage to the gate of the MOSFET 123 can be prevented at a cost lower than the case of using a high withstand voltage MOSFET.

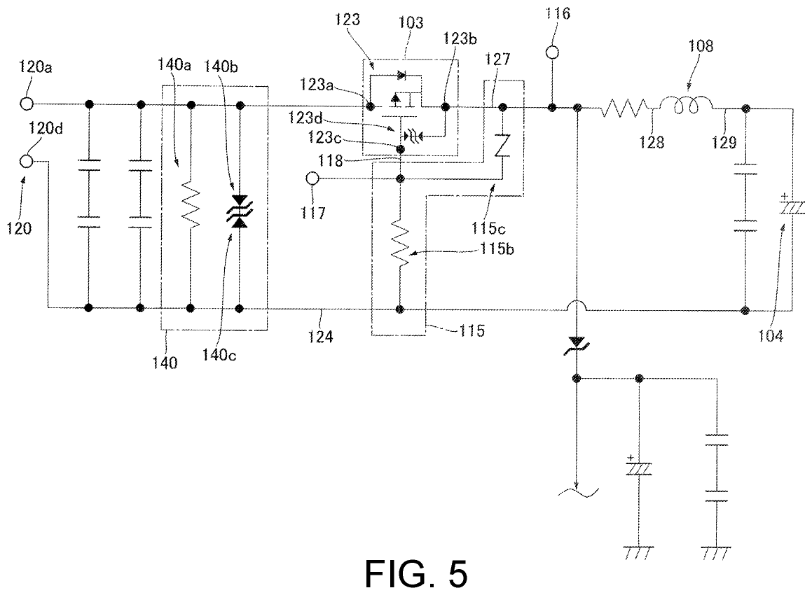

(8) In place of the bypass circuit 115 including the Zener diode 115a and the resistor 115b, the bypass circuit 115 may also be configured as including a varistor 115c and the resistor 115b, as shown in FIG. 5. The control substrate 101 shown in FIG. 5 includes the third substrate wiring 118 connected with the gate terminal 123c. The bypass circuit 115 includes the varistor 115c and the resistor 115b electrically interposed between the first substrate wiring 127 and the second substrate wiring 124 and serially connected with each other. The varistor 115c is electrically interposed between the first substrate wiring 127 and the third substrate wiring 118. The resistor 115b is electrically interposed between the third substrate wiring 118 and the second substrate wiring 124. The varistor voltage of the varistor 115c is lower than the withstand voltage between the gate and the source of the MOSFET 123.

In the control substrate 101 with such configuration, the output voltage from the vehicle-mounted battery 901, after starting to become higher than the rating, does not reach the withstand voltage between the gate and the source, but reaches the varistor voltage of the varistor 115c of the bypass circuit 115. Then, a current flowing from the first substrate wiring 127 to the GND via the bypass circuit 115 is generated. Then, by generating the current, the voltage between the gate and the source in the MOSFET 123 is maintained to be lower than the withstand voltage between the gate and the source. Thus, according to the control substrate 101 shown in FIG. 5, by using the bypass circuit 115 including the varistor 115c and the resistor 115b, the damage to the gate of the MOSFET 123 can be prevented at a cost lower than the case of using a high withstand voltage MOSFET.

(9) The first predetermined value is the varistor voltage.

According to such configuration, the damage to the gate of the MOSFET 123 can be prevented at a cost lower than the case of using a high withstand voltage MOSFET.

(10) The control substrate 101 shown in FIGS. 4 and 5 includes a first test point that conducts the first substrate wiring 127 and a second test point 117 that conducts the third substrate wiring 118.

According to the control substrate 101 with such configuration, the following is made possible by electrically connecting the first test point 116 and the second test point 117 with an inspection apparatus. That is, whether the electrical connection between the Zener diode 115a (or the varistor 115c) and the substrate wiring is poor can be checked, or the electrical properties of the Zener diode 115a (or the varistor 115c) in the bypass circuit 115 can be checked. In addition, according to the control substrate 101, by electrically connecting the second test point 117 and the GND terminal 120d with the inspection apparatus, whether the electrical connection between the resistor 115b and the substrate wiring is poor can be checked, or the electrical properties of the resistor 115b in the bypass circuit 115 can be checked. In addition, according to the control substrate 101, by electrically connecting the first test point 116 and the GND terminal 120d with the inspection apparatus, the electrical properties of the bypass circuit 115 can be checked.

(11) The control substrate 101 includes the first capacitor 104 consisting of an electrolytic capacitor, the motor driving circuit 150, and a fourth substrate wiring 129. The fourth substrate wiring 129 is connected with the first substrate wiring 127 via the choke coil 108, which is an electronic component, on the downstream side with respect to the first substrate wiring 127. The first capacitor 104 is interposed between any one of the first substrate wiring 127 and the fourth substrate wiring 129 and the second substrate wiring 124.

According to the control substrate 101 with such configuration, with the first capacitor 104 absorbing the ripple current from the external power supply through a charging function, the motor driving circuit 105 can drive the motor 11 at a stabilized rotation speed.

(12) The electric oil pump 1 includes the pump part 40, the motor 10 that drives the pump part 40, and the control substrate 101.

According to the electric oil pump 1 with such configuration, the motor 11 of the motor part 10 can be driven by using the low-cost control substrate 101 without using a high withstand voltage MOSFET in the bypass circuit 115.

Features of the above-described preferred embodiments and the modifications thereof may be combined appropriately as long as no conflict arises. While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A circuit substrate, comprising:
a substrate;
a positive electrode terminal and a GND terminal for inputting a direct current (DC) external power supply; and
a reverse connection protection circuit, protecting a circuit in the substrate in a case in which positive/negative of the external power supply are connected with the positive electrode terminal and the GND terminal in reverse,
wherein the reverse connection protection circuit comprises a MOSFET, and the circuit substrate comprises:
a first substrate wiring, connected with a source terminal of the MOSFET;
a second substrate wiring, connected with the GND terminal;
a bypass circuit, allowing, in a case where an output voltage of the external power supply is equal to or greater than a first predetermined value, a current to flow from the first substrate wiring to the second substrate wiring; and
a clamp circuit, connected with the positive electrode terminal and the GND terminal at an upstream side with respect to the MOSFET and clamping a positive voltage to a second predetermined value,
wherein the first predetermined value is a value smaller than a withstand voltage between a gate and a source of the MOSFET.

2. The circuit substrate as claimed in claim 1, wherein the clamp circuit comprises a diode pair which are a pair of Zener diodes serially connected with each other and allowing a current to flow in an opposite direction, clamps the positive voltage to the second predetermined value, and clamps a negative voltage to a third predetermined value.

3. The circuit substrate as claimed in claim 1, wherein the second predetermined value is a value smaller than a withstand voltage on a positive polarity side between a drain and the source of the MOSFET.

4. The circuit substrate as claimed in claim 2, wherein the second predetermined value is a value smaller than a withstand voltage on a positive polarity side between a drain and the source of the MOSFET.

5. The circuit substrate as claimed in claim 3, wherein an absolute value of the third predetermined value is a value smaller than an absolute value of a withstand voltage on a negative polarity side between the drain and the source of the MOSFET.

6. The circuit substrate as claimed in claim 4, wherein an absolute value of the third predetermined value is a value smaller than an absolute value of a withstand voltage on a negative polarity side between the drain and the source of the MOSFET.

7. The circuit substrate as claimed in claim 5, wherein each of the second predetermined value and the absolute value of the third predetermined value is a value greater than the first predetermined value.

8. The circuit substrate as claimed in claim 6, wherein each of the second predetermined value and the absolute value of the third predetermined value is a value greater than the first predetermined value.

9. The circuit substrate as claimed in claim 1, wherein the circuit substrate comprises a third substrate wiring connected with the gate terminal,
the bypass circuit comprises a Zener diode and a resistor electrically interposed between the first substrate wiring and the second substrate wiring and serially connected with each other,
the Zener diode is electrically interposed between the first substrate wiring and the third substrate wiring,
the resistor is electrically interposed between the third substrate wiring and the second substrate wiring, and
a Zener voltage of the Zener diode is lower than the withstand voltage between the gate and the source of the MOSFET.

10. The circuit substrate as claimed in claim 9, wherein the first predetermined value is the Zener voltage.

11. The circuit substrate as claimed in claim 1, wherein the circuit substrate comprises a third substrate wiring connected with the gate terminal,
the bypass circuit comprises a varistor and a resistor electrically interposed between the first substrate wiring and the second substrate wiring and serially connected with each other,
the varistor is electrically interposed between the first substrate wiring and the third substrate wiring,
the resistor is electrically interposed between the third substrate wiring and the second substrate wiring, and
a varistor voltage of the varistor is lower than the withstand voltage between the gate and the source of the MOSFET.

12. The circuit substrate as claimed in claim 11, wherein the first predetermined value is the varistor voltage.

13. The circuit substrate as claimed in claim 9, comprising:
a first test point, conducting the first substrate wiring; and
a second test point, conducting the third substrate wiring.

14. The circuit substrate as claimed in claim 11, comprising:
a first test point, conducting the first substrate wiring; and
a second test point, conducting the third substrate wiring.

15. The circuit substrate as claimed in claim 9, comprising:
an electrolytic capacitor; and
a motor driving circuit,
wherein the electrolytic capacitor is electrically interposed between any one of the first substrate wiring and a fourth substrate wiring and the second substrate wiring, and the fourth substrate wiring is connected with the first substrate wiring via an electronic component at a downstream side with respect to the first substrate wiring.

16. The circuit substrate as claimed in claim 11, comprising:
an electrolytic capacitor; and
a motor driving circuit,
wherein the electrolytic capacitor is electrically interposed between any one of the first substrate wiring and a fourth substrate wiring and the second substrate wiring, and the fourth substrate wiring is connected with the first substrate wiring via an electronic component at a downstream side with respect to the first substrate wiring.

17. An electric oil pump, comprising: a pump part, a motor part driving the pump part, and the circuit substrate as recited in claim 15.

18. An electric oil pump, comprising: a pump part, a motor part driving the pump part, and the circuit substrate as recited in claim 16.
